(19) United States
(12) Patent Application Publication
(10) Pub. No.: US 2008/0022522 A1
(43) Pub. Date: Jan. 31, 2008

(54) Manufacturing method for electrical connector

(75) Inventor: Ted Ju, Keelung (TW)

Correspondence Address: TROXELL LAW OFFICE PLLC;ONE SKYLINE PLACE, SUITE 1404, 5205 LEESBURG PIKE, FALLS CHURCH, VA, 22041, US

(73) Assignee: Lotes Co., Ltd.

(21) Appl. No.: 11/488,737

(22) Filed: Jul. 19, 2006

(51) Int. Cl. H05K 3/10; H01R 43/00

(52) U.S. Cl. 29/846; 29/884; 29/876

(57) ABSTRACT

The present invention discloses a manufacturing method for electrical connector, comprising the following steps: (1) provide an electrical insulating body disposed with a plurality of contact portions; (2) coat a first conductive layer of copper on the electrical insulating body with physical vapor deposition; (3) coat a second conductive layer of copper on the first conductive layer. A manufacturing method of electrical connector according to the present invention provides a simply manufacturing process without many steps of compressing or bending to process conductive terminals, guarantees a good quality of electrical conduction from the coated layer, and provides an effective contact between the electrical connector and its butted electronic devices.

### FIELD OF THE INVENTION

The present invention relates to a manufacturing method for electrical connectors and, in particular, to a manufacturing process for electrical connectors without the need to process conductive terminals.

### BACKGROUND OF THE INVENTION

Conventional electrical connector generally comprises an electrical insulating body and conductive terminals received in the electrical insulating body. The electrical insulating body described above is provided with conductive terminal accommodating holes into which the conductive terminals are received, wherein the conductive terminal is provided with contact portions arranged on its both sides and a securing portion. Two butted electronic devices are compressingly contacted to achieve the electrical connection. This kind of conductive terminal, however, has a complex shape and is produced by processing metal in a complicated process. Because the manufacturing involves many steps of compressing and bending, plastic deformation is resulted and thus the electrical connector and its butted electronic device cannot achieve effective contact, the performance of the electrical connector is therefore negatively affected.

Consequently, it is necessary to provide a manufacturing method for electrical connector to overcome the drawbacks described above.

### SUMMARY OF THE INVENTION

An object of the present invention is to provide a manufacturing process for electrical connector, which is a simple process and is able to produce an electrical connector to achieve good electrical contact with its butted electronic devices.

To achieve the objects described above, a manufacturing method for electrical connector according to the present invention comprises the following steps: (1) provide an electrical insulating body disposed with a plurality of contact portions; (2) coat a first conductive layer of, for example but not limited to, copper on the electrical insulating body with physical vapor deposition; (3) coat a second conductive layer of, for example but not limited to, copper on the first conductive layer.

Compared with the conventional art, a manufacturing method of electrical connector according to the present invention provides a simply manufacturing process without many steps of compressing or bending to process conductive terminals, guarantees a good quality of electrical conduction from the coated layer, and provides an effective contact between the connector and its butted electronic devices.

### BRIEF DESCRIPTION OF THE DRAWINGS

The present invention can be more fully understood by reference to the following description and accompanying drawings, in which:

FIG. 1 schematically illustrates the flow chart of a preferred embodiment of a manufacturing method for electrical connector according to the present invention;

FIG. 2 schematically illustrates an electrical connector coated with conductive layers according to a manufacturing method for electrical connector of the present invention;

FIG. 3 schematically illustrates another view angle of the electrical connector of FIG. 2;

FIG. 4 schematically illustrates a partial enlargement of the electrical connector of FIG. 2;

FIG. 5 schematically illustrates a partial enlargement of the electrical connector of FIG. 3;

FIG. 6 schematically illustrates a local cross-sectional view of the electrical connector of FIG. 2;

FIG. 7 schematically illustrates a partial enlargement of the electrical connector of FIG. 6; and

FIG. 8 schematically illustrates another electrical connector coated with conductive layers according to the present invention.

### DETAILED DESCRIPTION OF THE INVENTION

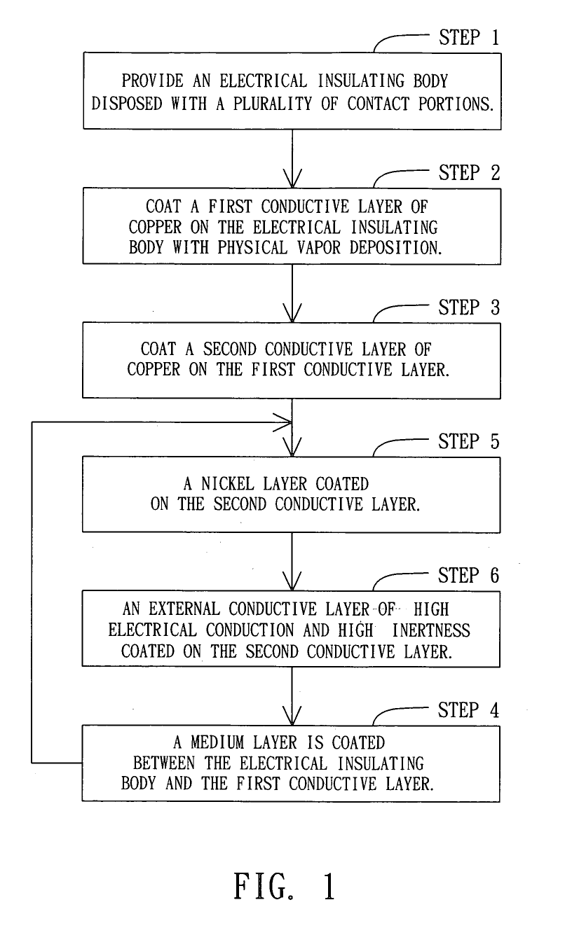

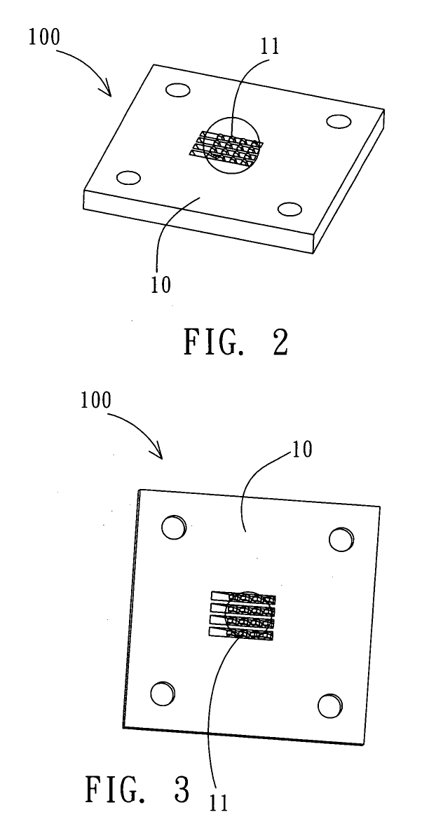

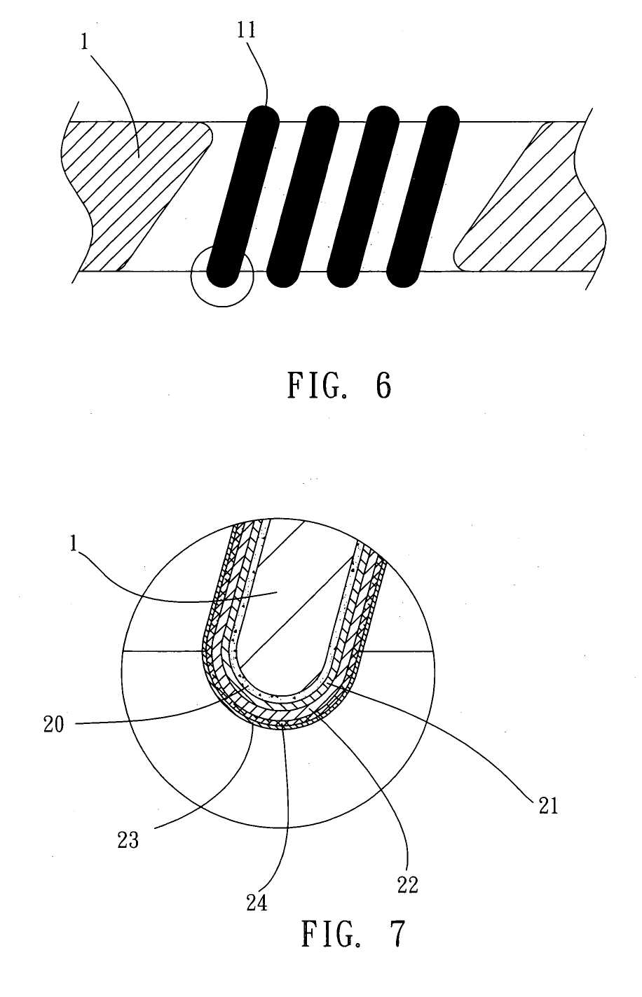

Referring to FIGS. 1 to 7, a manufacturing method for electrical connector according to the present invention comprises the following steps: (1) provide an electrical insulating body 1 disposed with a plurality of contact portions 11 (step 1); (2) coat a first conductive layer 21 on the electrical insulating body 1 with physical vapor deposition (step 2); (3) coat a second conductive layer 22 on the first conductive layer 21 (step 3).

In the step 1, an electrical insulating body 1 made of high elasticity of polymer is provided, comprising a non-conductive main body 10, a plurality of conductive contact portions 11 protruding out of the upper and lower surfaces of the main body 10, and a connection portion 12 connecting the main body 10 and the contact portions 11 (only part of the contact portion 11 and the connection portion 12 are shown). The contact portion 11 is elastic in nature and may be compressing contacted with external electronic devices (chip module or circuit board for example, not shown). Also, the contact portion 11 may swing relative to the main body 10 of the electrical insulating body 1.

In the step 2, physical vapor deposition is used to coat a first conductive layer 21 of, for example but not limited to, copper on the electrical insulating body 1. The physical vapor deposition is conducted by, for example but not limited to, vacuum sputtering.

In the step 3, the second conductive layer 22 of, for example but not limited to, copper is coated on the first conductive layer 21 by electroplating. The aim of coating the second conductive layer 22 is to increase the thickness of the first conductive layer 21.

Furthermore, a manufacturing method for electrical connector according to the present invention further comprises a medium layer 20 between the electrical insulating body 1 and the first conductive layer 21 (step 4) so as to increase the adhesion between the electrical insulating body 1 and the first conductive layer 21.

Moreover, a manufacturing method for electrical connector according to the present invention further comprises a nickel layer 24 coated on the second conductive layer 22 (step 5) so as to enhance the wear resistance of the contact portion 11 and the corrosion resistance of the electrical connector.

Furthermore, a manufacturing method for electrical connector according to the present invention further comprises an external conductive layer 23 of high electrical conduction and high inertness coated on the second conductive layer 22 (step 6) so as to enhance the service life and conductive performance of the electrical connector, wherein the external conductive layer 23 in the present embodiment is, for example but not limited to, gold (of course, it may be, for example but not limited to, silver, palladium, or other metals with similar properties). The external conductive layer 23 of high electrical conduction and high inertness may only be coated on the first conductive layer 21 so as to save the amount of noble metal used and thus cut cost.

The manufacture of the electrical connector is completed after the deposition of the external conductive layer 23 and an electrical connector 100 with both ends being compressed is finished. When external electronic devices (chip module or circuit board, not shown, for example) is connected to the electrical connector, both ends of the electrical connector are compressed to render the contact portion 11 deformed. Since the connection portion 12 connects the contact portion 11 with the main body 10 and the contact portion 11 may swing relative to the main body 10 through the connection portion 12, the amount of deformation may be concentrated on the connection portion 12 if the contact portion 11 is deformed. Consequently, the contact portion 11 may be prevented from cracking on its metal layers due to high contact force.

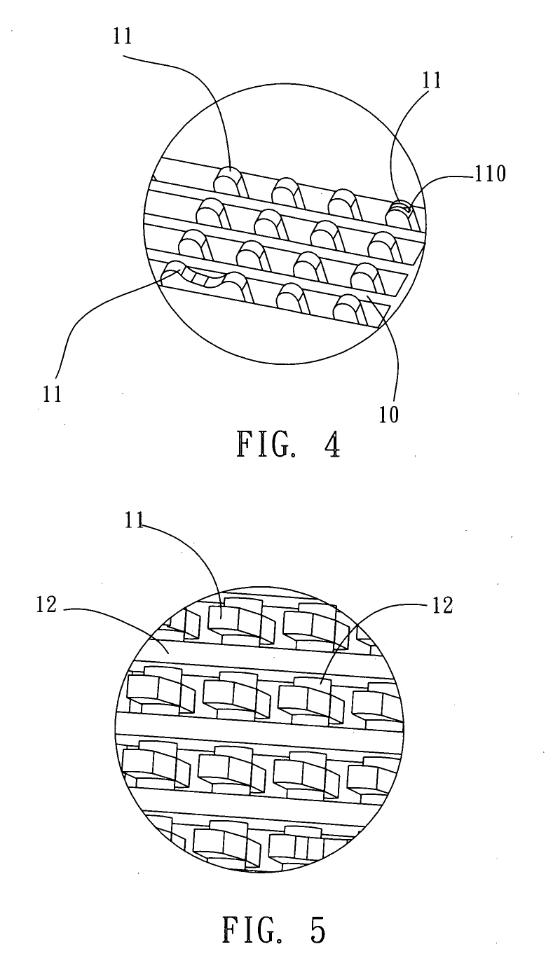

To enable the contact portion 11 to connect with different connecting points, the contact portion 11 may have different sizes. One contact portion 11 in FIG. 4, for example, is larger than the others. Also, it may be possible to dispose an indent 110 on one contact portion 11, as shown in FIG. 4, to achieve a multi-point contact.

A manufacturing method of electrical connectors according to the present invention provides a simply manufacturing process without many steps of compressing or bending to process conductive terminals, a good quality of electrical conduction with coated layer, and a contact portion 11 protruding out of the surface of the electrical insulating body 1 to form compressing contact with the external electronic devices. Consequently, an electrical connector produced by the manufacturing method according to the present invention may prevent its conductive terminals from failure due to plastic deformation after repetitive compressing and bending and achieve an effective contact with butted electronic devices.

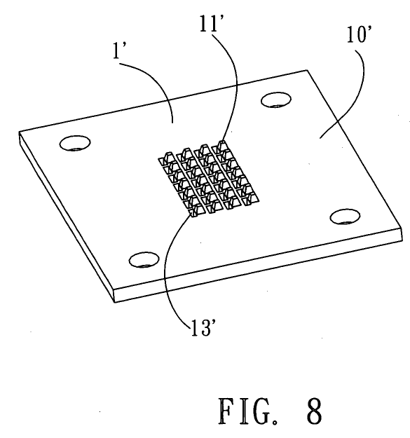

FIG. 8 shows another electrical connector manufactured by a manufacturing method of electrical connectors according to the present invention. The contact portion 11′ of the electrical connector cannot swing relative to the main body 10′ of the electrical insulating body 1′ and an accommodating space 13′ is provided between the adjacent contact portions 11′ to accommodate the deformation of the contact portion 11′, with which the objects described above may also be achieved.

While the invention has been described with reference to the a preferred embodiment thereof, it is to be understood that modifications or variations may be easily made without departing from the spirit of this invention, which is defined by the appended claims.

What is claimed is:

1. A manufacturing method for electrical connector, comprising the following steps:
provide an electrical insulating body disposed with a plurality of contact portions;
coat a first conductive layer on the electrical insulating body with physical vapor deposition; and
coat a second conductive layer on the first conductive layer.

2. The manufacturing method as defined in claim 1, wherein the first conductive layer may be copper.

3. The manufacturing method as defined in claim 1, wherein the second conductive layer may be copper.

4. The manufacturing method as defined in claim 1, wherein the second conductive layer is coated on the first conductive layer.

5. The manufacturing method as defined in claim 1, wherein a medium layer is provided between the electrical insulating body and the first conductive layer.

6. The manufacturing method as defined in claim 1, wherein a nickel layer coated on the second conductive layer.

7. The manufacturing method as defined in claim 6, wherein an external conductive layer of high electrical conduction and high inertness is coated on the second conductive layer.

8. The manufacturing method as defined in claim 7, wherein the external conductive layer may be gold.

9. The manufacturing method as defined in claim 7, wherein the external conductive layer may be silver.

10. The manufacturing method as defined in claim 7, wherein the external conductive layer may be palladium.

11. The manufacturing method as defined in claim 1, wherein the physical vapor deposition is conducted by vacuum sputtering.

12. The manufacturing method as defined in claim 1, wherein the electrical insulating body is made of high elasticity of polymer.

13. The manufacturing method as defined in claim 1, wherein part of the electrical insulating body forms a conductive contact portion and part of the electrical insulating body forms a non-conductive main body, and a connection portion is provided between the contact portion and the main body.
